(19) United States
(12) Patent Application Publication
(10) Pub. No.: US 2014/0125963 A1
(43) Pub. Date: May 8, 2014

(54) EXPOSURE APPARATUS RECOVERY METHOD AND EXPOSURE APPARATUS

(71) Applicant: Canon Kabushiki Kaisha, Tokyo (JP)

(72) Inventor: Yasuhiro WATANABE, Utsunomiya-shi (JP)

(73) Assignee: CANON KABUSHIKI KAISHA, Tokyo (JP)

(21) Appl. No.: 14/071,770

(22) Filed: Nov. 5, 2013

(30) Foreign Application Priority Data
Nov. 6, 2012 (JP) 2012-244320

(51) Int. Cl. G03F 7/20

(52) U.S. Cl. CPC G03F 7/70425
USPC 355/77

(57) ABSTRACT

A recovery method for recovering an exposure apparatus that exposes a pattern image onto a substrate in a case that certain processing has not normally ended is provided that includes the steps of registering a plurality of processing methods to the processing in advance; determining whether or not the processing has normally ended each time the processing is performed; associating and storing the number of times the processing has been performed and the number of times the processing has normally ended with the processing method employed when the processing has been performed, as history information; and selecting the processing method to be next employed from the plurality of processing methods based on the history information in a case that the processing has not normally ended.

### BACKGROUND OF THE INVENTION

1. Field of the Invention

The present invention relates to a recovery method to be used upon occurrence of abnormalities in an exposure apparatus and an exposure apparatus that performs recovery.

2. Description of the Related Art

An exposure apparatus is an apparatus that transfers a pattern of an original plate (reticle or the like) onto a photosensitive substrate (e.g., wafer or the like where the surface thereof is coated with a resist layer) via a projection optical system in a lithography step included in manufacturing steps for a semiconductor device, a liquid crystal display device, and the like. In recent years, there has been a demand for not only an exposure apparatus that enables further miniaturization but also an exposure apparatus that has high productivity with improvement in operation rate. Such an exposure apparatus is generally operated continuously day and night without interruption. Thus, a down time during which exposure processing is not performed affects productivity even if the down time is a planned time. Furthermore, when the exposure apparatus cannot be suddenly used, the productivity is further reduced. Accordingly, one countermeasure is to suppress a down time so as to realize improvement in operation rate. In particular, when abnormalities occur in the exposure apparatus, it is important to recover the apparatus as quickly as possible. In connection with the recovery method, Japanese Patent Laid-Open No. 2001-307998 discloses an exposure apparatus that re-measures the position of a substrate with reference to the measurement position, which has been calculated based on a plurality of measurement information stored as history information, as a reference when abnormalities occur during substrate alignment measurement. Japanese Patent No. 3919294 discloses a remote maintenance system for industrial apparatus that stores an abnormal state and an abnormality eliminating method in advance and presents abnormal state information in order to quickly deal with abnormality when abnormalities occur in the apparatus.

Here, when the exposure apparatus recognizes that abnormalities have occurred during operation thereof, the exposure apparatus attempts to achieve recovery from the abnormal state by performing retry processing or changing and adjusting parameters in response to the content of abnormalities. Conventionally, the recovery method for recovering the abnormal state at this time is general purpose (redundant) since the recovery of any process, any lot, or any device is assumed. Thus, it is assumed that not only the actually required processing but also redundant processing are performed upon recovery. Consequently, the recovery time becomes long, which may affect the productivity of the exposure apparatus. In this regard, Japanese Patent Laid-Open No. 2001-307998 is only related to substrate alignment measurement, and does not describe a recovery method to be performed when abnormalities occur during processing other than alignment measurement. In Japanese Patent No. 3919294, the remote maintenance system stores an abnormal state and an abnormality eliminating method in advance and only presents abnormal, state information when abnormalities occur. Thus, there is no description of how the remote maintenance system actually performs the abnormality eliminating method.

### SUMMARY OF THE INVENTION

The present invention provides, for example, a recovery method advantageous to reduction of recovery time for abnormalities occurred in an exposure apparatus.

According to an aspect of the present invention, a recovery method for recovering an exposure apparatus that exposes a pattern image onto a substrate when certain processing has not normally ended is provided that includes the steps of registering a plurality of processing methods to the processing in advance; determining whether or not the processing has normally ended each time the processing is performed; associating and storing the number of times the processing has been performed and the number of times the processing has normally ended with the processing method employed when the processing has been performed, as history information; and selecting the processing method to be next employed from the plurality of processing methods based on the history information when the processing has not normally ended.

Further features of the present invention will become apparent from the following description of exemplary embodiments with reference to the attached drawings.

### BRIEF DESCRIPTION OF THE DRAWINGS

FIG. 1 is a diagram illustrating the system configuration of an exposure apparatus according to a first embodiment of the present invention.

FIG. 2 is a diagram illustrating the configuration of an exposure unit according to the first embodiment of the present invention.

FIG. 3 is a flowchart illustrating the flow of a recovery method according to the first embodiment of the present invention.

### DESCRIPTION OF THE EMBODIMENTS

Hereinafter, preferred embodiments of the present invention will now be described in detail with reference to the accompanying drawings.

### First Embodiment

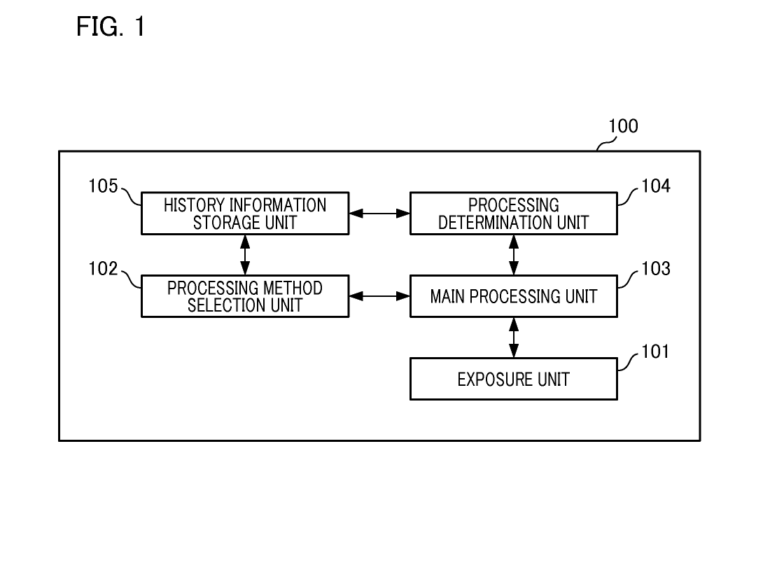

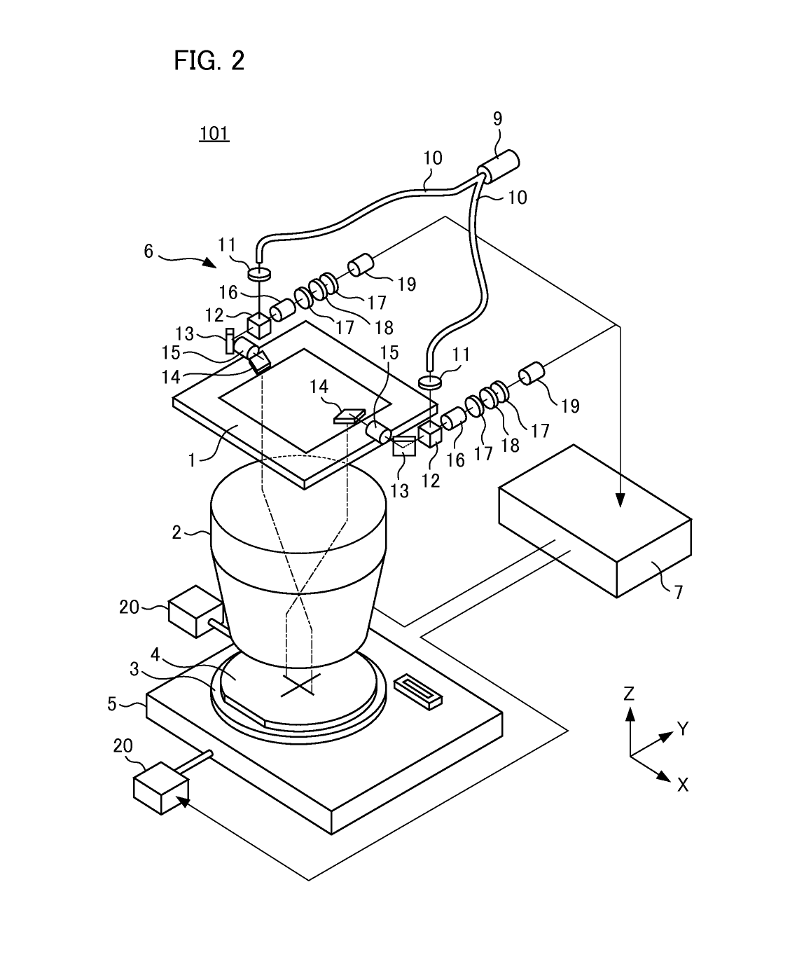

Firstly, a description will be given of an exposure apparatus and its recovery method according to a first embodiment of the present invention. An example of the exposure apparatus of the present embodiment is a projection type exposure apparatus that is used in the steps of manufacturing a semiconductor device and transfers a pattern (for example, circuit pattern) formed on a reticle onto a wafer (substrate) serving as a substrate to be processed using a step-and-repeat system. FIG. 1 is a block diagram illustrating the system configuration of an exposure apparatus 100 according to the present embodiment. The exposure apparatus 100 includes an exposure unit 101 that exposes a wafer 4 (see FIG. 2), a processing method selection unit 102 relating to a recovery method to be described below, a main processing unit 103, a processing determination unit 104, and a history information storage unit 105. Hereinafter, a description will be firstly given of the exposure unit 101.

FIG. 2 is a schematic perspective view illustrating the configuration of the exposure unit 101. The exposure unit 101 includes an illumination system (not shown) including an exposure light source, a reticle stage (not shown) for holding a reticle 1, a projection optical system 2, a wafer stage 5 for holding the wafer 4 via a chuck 3, an alignment optical system 6, and a controller 7. The reticle 1 is, for example, an original plate made of quartz glass, where the pattern to be transferred is formed on the wafer 4. The wafer 4 is a substrate made of single crystal silicon. A resist (photoresist) is applied to the surface of the wafer 4. In FIG. 2, the Z axis is aligned parallel to the optical axis (in the present embodiment, the vertical direction) of the projection optical system 2, the X axis is aligned in the scanning direction of the wafer 4 upon exposure within a plane perpendicular to the Z axis, and the Y axis is aligned in the non-scanning direction orthogonal to the X axis. The reticle stage is movable in both the X-axis and Y-axis directions while holding the reticle 1. The projection optical system 2 transfers the pattern on the reticle 1, which has been illuminated with exposure light from the illumination system, onto the wafer 4 with a predetermined magnification (for example, ½ to ⅕). The wafer stage 5 is movable at least in both the X-axis and Y-axis directions while holding the wafer 4. The alignment optical system 6 is arranged above the reticle 1. Firstly, an illumination optical system 9 irradiates the reticle 1 with illumination light via an optical system consisting of a fiber 10, a focusing lens 11, a beam splitter (half mirror) 12, a first mirror 13, a second mirror 14, and an objective lens 15. Here, the illumination light passed through the reticle 1 reaches the wafer 4 via the projection optical system 2. On the other hand, reflection light from the reticle 1 and the wafer 4 returns back to the original optical path and passes through the beam splitter 12 to thereby be imaged on a CCD camera 19 via an optical system consisting of a relay lens 16, an erector lens 17 and a space filter 18. The controller 7 may control the operation and adjustment of the components of the exposure unit 101. In particular, upon alignment measurement, the controller 7 processes data acquired from the alignment optical system 6 and then executes alignment error correction processing for driving the wafer stage 5 with respect to a stage drive system 20 based on the processing result. Also, the controller 7 is constituted, for example, by a computer or the like and is connected to the components of the exposure unit 101 via a line to thereby execute control of the components in accordance with a program or the like. Note that the controller 7 may be integrated with the other parts of the exposure unit 101 (provided in a shared housing) as shown in FIG. 2 or may be provided separately from the other parts of the exposure unit 101 (provided in a separate housing) so as to be integrated with, for example, the units relating to recovery processing provided in the exposure apparatus 100 shown in FIG. 1.

Referring back to FIG. 1, when abnormalities occur in the exposure apparatus 100 during some processing and the exposure apparatus 100 is recovered from the abnormalities, the processing method selection unit (selection unit) 102 acquires history information from the history information storage unit 105 to be described below to thereby select an optimum processing method. The main processing unit 103 acquires a processing method from the processing method selection unit 102 and then transmits the acquired processing method to the exposure unit 101. Also, the main processing unit 103 acquires the processing content and the processing result from the exposure unit 101 after processing has been carried out, and then transmits these information as processing information to the processing determination unit 104. The processing determination unit (determination unit) 104 determines whether or not the processing result obtained by the exposure unit 101 is normal or abnormal based on the acquired processing information, and transmits the determination result together with the processing information to the history information storage unit 105. The history information storage unit (storage unit) 105 is, for example, a magnetic storage medium such as a hard disk, a nonvolatile storage medium such as a flash memory, or the like and stores the processing information and the determination result as history information. Note that the processing method selection unit 102, the main processing unit 103, and the processing determination unit 104 may be constituted by, for example, a computer (including a board computer). The processing method selection unit 102, the main processing unit 103, and the processing determination unit 104 may be separately or integrally configured and the present invention is not particularly limited thereto.

Next, a description will be given of various types of processing performed by the exposure apparatus 100. In general, in the exposure apparatus, a down time needs to be suppressed as much as possible from the viewpoint of improvement in productivity. In connection with this, when abnormalities occur during a certain processing step, the exposure apparatus 100 of the present embodiment particularly implements a recovery method as described below for eliminating abnormalities and then getting back to normal processing so as to reduce a recovery time. Hereinafter, in the present embodiment, a description will be given of the recovery method based on the assumption that when abnormalities occur in measurement in, for example, a TV pre-alignment measurement step. The TV pre-alignment measurement refers to measurement for aligning the alignment mark provided on the wafer 4 with the alignment position. In this manner, the alignment of the wafer 4 is roughly made. During the TV pre-alignment measurement, the wafer position (positional information) in the previous measurement obtained when measurement has normally ended is stored and updated as an apparatus offset. Then, the stored positional information is read to thereby detect an alignment mark based on the read positional information in the next measurement.

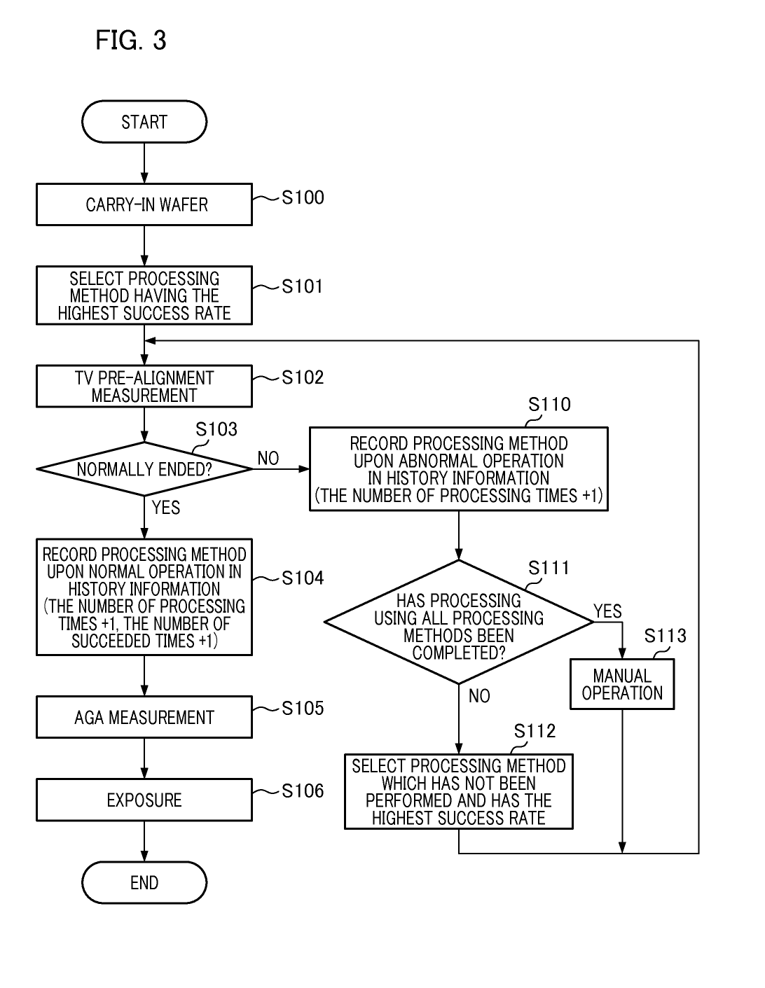

FIG. 3 is a flowchart illustrating a series of processing steps from wafer carry-in to exposure in the exposure apparatus 100 in order to explain the recovery method according to the present embodiment. Firstly, the wafer 4 to be exposed is carried in the exposure apparatus 100 (step S100). Then, the processing method selection unit 102 acquires history information from the history information storage unit 105 to thereby select an optimum processing method for TV pre-alignment measurement (step S101). Note that the optimum processing method refers to a processing method having the highest priority with reference to evaluation items, i.e., a processing method having the highest success rate in the present embodiment.

Table 1 is a table illustrating exemplary storage information which includes the above history information and may be stored in the history information storage unit 105. The storage information includes various types of processing to be performed by the exposure apparatus 100, a plurality of processing methods that are capable of performing various types of processing, and the number of processing times, the number of succeeded times, and the success rate that are associated with these processing methods and are stored as history information. Here, various types of processing to be performed by the exposure apparatus 100 refers to various types of pre-registered processing in which abnormalities may occur during operation. In the present embodiment, a description will be given of TV pre-alignment measurement as described above as various types of processing but Table 1 also illustrates focus measurement as processing other than TV pre-alignment measurement. The processing methods are different from one another depending on the type of processing in which abnormalities are assumed to occur. When the processing is TV pre-alignment measurement, substitute mark using, illumination mode switching, mark searching, substitute shot using, and the like are contemplated. In the present embodiment, these four processing methods are intended to be included. Here, the term “substitute mark using” refers to a measurement method by changing the alignment mark to be measured to another alignment mark when the alignment mark to be measured cannot be detected due to breakage or the like. The term “illumination mode switching” refers to a measurement method by switching an illumination mode to correspond to the process, which is effective because the detection power of the alignment mark may change due to the process factors. The term “mark searching” is a method for re-measuring the alignment mark after the alignment mark to be measured has been searched again by the alignment optical system 6. The term “substitute shot using” is a method for measuring an alignment mark by changing a shot (pattern transfer region) when the alignment mark to be measured cannot be detected due to misalignment of the shot transferred onto the wafer 4. As a reference, when the processing is focus measurement, it is contemplated that the processing methods are, for example, wavelength switching, light controlling, and the like. The number of processing times and the number of succeeded times which are included in history information are recorded (counted) on a case-by-case basis in the specific processing step to be described below. The success rate is an evaluation item in the present embodiment and is an evaluation value which is calculated by dividing the number of succeeded times by the number of processing times. Note that, in step S101, the processing method in a case where history information is not yet recorded due to the first exposure operation is determined by a user in advance.

TABLE 1

| | | History | | |
|---|---|---|---|---|
| | | The number | The number | |
| | | of processing | of succeeded | Success |
| Processing | Processing method | times | times | rate |
| TV pre- | Substitute mark | 10 | 8 | 0.8 |
| alignment | using | | | |
| measure- | Illumination mode | 4 | 2 | 0.5 |
| ment | switching | | | |
| | Mark searching | 20 | 15 | 0.75 |
| | Substitute shot | 0 | 0 | 0 |
| | using | | | |
| Focus | Wavelength | 10 | 5 | 0.5 |
| measure- | switching | | | |
| ment | Light adjusting | 5 | 5 | 1 |
| . . . | . . . | . . . | . . . | . . . |

Next, the main processing unit 103 transmits the selected processing method to the exposure unit 101, and the controller 7 causes the alignment optical system 6 to perform TV pre-alignment measurement using the selected processing method (step S102). For example, when current history information is as shown in Table 1, the processing method having the highest success rate from among the registered four processing methods is “substitute mark using”. Thus, in step S102, the TV pre-alignment measurement is performed by “substitute mark using”. Next, the processing determination unit 104 determines whether or not the TV pre-alignment measurement has normally ended in step S102 (step S1.03). Here, whether the result of the TV pre-alignment measurement is normal or abnormal is determined by a correlation degree between the alignment mark measured at this time and the template of the alignment mark prepared in advance. In this case, if the correlation degree exceeds a certain threshold value, the processing determination unit 104 determines that the result of the TV pre-alignment measurement is normal, whereas if the correlation degree does not exceed a certain threshold value, the processing determination unit 104 determines that the result of the TV pre-alignment measurement is abnormal. In addition, the processing determination unit 104 also determines that the result of the TV pre-alignment measurement is abnormal when detection of the alignment mark to be measured was unsuccessful. As an example, an offset may occur in the detection position of the alignment mark due to differences among lots, machines, and the like. More specifically, when the wafer exposed by an exposure apparatus A is aligned with the wafer exposed by an exposure apparatus B, a positional shift may occur due to an offset in the exposure apparatus A. In this case, since the correlation degree does not exceed a threshold value, the processing determination unit 104 determines that the current TV pre-alignment measurement has not normally ended, and thus, the result of the TV pre-alignment measurement is abnormal.

When the processing determination unit 104 determines in step S103 that the TV pre-alignment measurement has normally ended (YES), the process shifts to step S104. Firstly, the processing determination unit 104 stores the processing method performed when the TV pre-alignment measurement has normally ended as history information in the history information storage unit 105 (step S104). More specifically, the processing determination unit 104 updates the number of processing times and the number of succeeded times of the TV pre-alignment measurement using the processing method so as to add 1 to these numbers and stores the updated information in the history information storage unit 105. Next, the controller 7 performs AGA (Advanced Global Alignment) measurement which is alignment processing (step S105). Then, the controller 7 causes the exposure unit 101 to expose the wafer 4 (step S106), and a series or processing steps ends.

On the other hand, when the processing determination unit 104 determines in step S103 that the TV pre-alignment measurement is abnormal, the process shifts to step S110. Firstly, the processing determination unit 104 stores the processing method performed when the TV pre-alignment measurement is abnormal as history information in the history information storage unit 105 (step S110). More specifically, the processing determination unit 104 updates the number of processing times of the TV pre-alignment measurement using the processing method so as to add 1 to the number of processing times of the TV pre-alignment measurement and stores the updated information in the history information storage unit 105. On the other hand, the processing determination unit 104 updates the number of processing times but does not update the number of succeeded times.

Next, the processing determination unit 104 determines whether or not measurement using all processing methods (the registered four processing methods) has been attempted (step S111). Here, when the processing determination unit 104 determines that measurement using all processing methods has not been attempted (NO), the process shifts to step 3112. Next, the processing method selection unit 102 acquires history information from the history information storage unit 105, and selects a processing method which has not been performed and has the highest success rate as the next processing method (step S112). For example, when the current TV pre-alignment measurement is performed by “substitute mark using” and it is determined that the abnormalities of the measurement at that time have occurred, the remaining three processing methods are not yet performed from among the registered four processing methods. In this case, the processing method selection unit 102 selects “mark searching” with the highest success rate among the remaining three processing methods as the next processing method. Then, the process returns to step S102, and the controller 7 performs the TV pre-alignment measurement using the processing method selected in step S112. Consequently, the exposure apparatus 100 repeats selection of a processing method and measurement using the selected processing method until abnormalities are eliminated or the registered processing methods are exhaustively performed. As an exemplary reference, when the current TV pre-alignment measurement is performed by “mark searching” but abnormalities are not eliminated, the processing method which is not yet performed and has the highest success rate from among the registered four processing methods is “illumination mode switching”. Thus, the processing method selection unit 102 next selects “illumination mode switching” as the processing method.

On the other hand, when the processing determination unit 104 determined in step Sill that measurement by all processing methods has been attempted, that is, all of the registered processing methods has been performed but recovery could not be made by any method (YES), the process shifts to step S113. Next, the processing method selection unit 102 selects a manual operation by an operator and prompts the operator to manually perform recovery processing on a display unit (not shown) or the like included in the exposure apparatus 100. Next, after recovery by the manual operation in step S113 has been completed, the process returns to step 3102, and the controller 7 performs the TV pre-alignment measurement again. Next, when the processing determination unit 104 determines in step S103 that the TV pre-alignment measurement has normally ended, the processing determination unit 104 stores the processing method performed when the TV pre-alignment measurement has normally ended as new history information in the history information storage unit 105 in step S104. At this time, since the TV pre-alignment measurement using the processing method at this time is performed for the first time, the processing determination unit 104 updates the number of processing times and the number of succeeded times of the TV pre-alignment measurement as new history information and stores the updated information in the history information storage unit 105.

As described above, the recovery method of the present embodiment attempts recovery in sequence from the processing method having the highest success rate when abnormalities occur during processing such as TV pre-alignment measurement or the like. Thus, redundant processing which is not essentially required is not performed, and thus, there is a high probability that a recovery time is shortened, so that the influence on productivity can be suppressed as much as possible. Although the above description has been given of the recovery method by taking an example of TV pre-alignment measurement as target processing (processing to which the present embodiment is applicable), the present invention is not limited to the TV pre-alignment measurement but any processing performed by the exposure apparatus 100 may be targeted. In contrast, in the recovery method, target processing is not necessarily set to a plurality of processings such as TV pre-alignment measurement, focus measurement, or the like but may also be dedicated to, for example, TV pre-alignment measurement.

As described above, according to the present embodiment, for example, a recovery method advantageous to reduction of the recovery time for abnormalities occurred in an exposure apparatus may be provided.

### Second Embodiment

Next, a description will be given of an exposure apparatus and its recovery method according to a second embodiment of the present invention. A feature of the exposure apparatus and its recovery method according the present embodiment lies in the fact that a plurality of “processing conditions” corresponding to each processing method is included in storage information shown in the first embodiment. Table 2 is a table illustrating storage information according to the present embodiment in which the item of processing condition is added to Table 1 according to the first embodiment. For example, there is “substitute mark using” as one of the processing methods for TV pre-alignment measurement, but the success rate differs depending on the specific condition. One of such a condition includes, for example, the shape pattern of an alignment mark. Thus, in the present embodiment, the condition is included as a “processing condition” in information, and, when the processing method selection unit 102 selects a processing method in steps S101 and S112 in the first embodiment, the processing method selection unit 102 references a success rate taking into account the processing method and the processing condition. For example, assume that current history information is as shown in Table 2 in step S101. In this case, a combination of a processing method and a processing condition having the highest success rate among a plurality of registered processing methods and processing conditions is that the processing method is “substitute mark using” and the processing condition is “shape pattern A”. Thus, in the subsequent step S102, the TV pre-alignment measurement is performed by “substitute mark using” under the condition of “shape pattern A”. Furthermore, for example, assume that the current TV pre-alignment measurement is performed by “substitute mark using” under the condition of “shape pattern A” in step S103 and it is determined that the abnormalities of measurement at that time have occurred. In this case, in the subsequent step S112, the processing method selection unit 102 selects “illumination mode switching” and “wavelength: A, light quantity: B” having the highest success rate from among the combinations of the remaining processing methods and processing conditions as the next processing method. According to the present embodiment, a success rate (evaluation item) which is calculated for case division more than that of the first embodiment is employed, resulting in an improvement in capability of successful recovery.

TABLE 2

| | | | History | | |
|---|---|---|---|---|---|
| | | | The | The | |
| | | | number of | number of | |
| | Processing | Processing | processing | succeeded | Sucess |
| Processing | method | condition | times | times | rate |
| TV pre- | Substitue | Shape pattern A | 10 | 8 | 0.8 |
| alignment | mark | Shape pattern B | 4 | 2 | 0.5 |
| measure- | using | . . . | . . . | . . . | . . . |
| ment | Illumi- | Wavelength: A, | 10 | 7 | 0.7 |
| | nation | Light quantity: B | | | |
| | mode | Wavelength: A′, | 4 | 2 | 0.5 |
| | switching | Light quantity: B′ | | | |
| | | . . . | . . . | . . . | . . . |
| | . . . | . . . | . . . | . . . | . . . |

### Third Embodiment

Next, a description will be given of an exposure apparatus and its recovery method according to a third embodiment of the present invention. In the above embodiments, a success rate is used as an evaluation item so as to perform selection of a processing method and a processing condition. In the recovery method by use of a success rate, the processing time taken to the selected processing method is not taken into account. However, the processing time may preferably be short from the viewpoint of suppressing a reduction in productivity. Here, the processing time refers to an average processing time from the start to the end of processing when certain processing is performed. On the other hand, it is also contemplated in some cases that a user may want to prioritize highly accurate processing rather than a reduction in processing time. In this case, accuracy (measurement accuracy when processing is TV pre-alignment measurement) may also be used as an evaluation item. Here, the term “accuracy” refers to the mean value of the error (misalignment) when certain processing is performed, and the processing method is performed with high accuracy with decrease in the value. With these taken into account, in the present embodiment, a plurality of “processing times” and “accuracy” corresponding to each processing method is included in history information shown in the first embodiment. Table 3 corresponds to Table 1 according to the first embodiment and is a table illustrating storage information according to the present embodiment in which the items of processing time and accuracy in addition to success rate are added as history information.

TABLE 3

| | | History | | |
|---|---|---|---|---|
| | | Success | Processing time | Accuracy |
| Processing | Processing method | rate | [sec] | [nm] |
| TV pre- | Substitute | 0.8 | 10 | 4 |
| alignment | mark using | | | |
| measurement | Illumination mode | 0.5 | 30 | 5 |
| | switching | | | |
| | Mark searching | 0.75 | 120 | 4 |
| | Substitute, | 0 | 60 | 6 |
| | shot using | | | |
| Focus | Wavelength | 0.5 | 10 | 20 |
| measurement | switching | | | |
| | Light adjusting | 1 | 90 | 25 |
| . . . | . . . | . . . | . . . | . . . |

Here, in order to facilitate priority determination of the evaluation item values (values as specified in Table 3) by the processing method selection unit 102, the concept of evaluation values for evaluation items is introduced as follows. Table 4 is a table illustrating the results of calculating the evaluation values for the processing methods for TV pre-alignment measurement as an example by setting success rate, processing time, and accuracy in history information in Table 3 as evaluation items. The evaluation values are normalized such that the minimum value is 0 and the maximum value is 1 for each evaluation item. Firstly, the evaluation value in the case of a processing method where high evaluation is given with an increase in evaluation value is a value obtained by dividing the value for the evaluation item by the summation of the values for all evaluation items. For example, such an evaluation item is success rate which is the same as that in the above embodiments. On the other hand, the evaluation value in the case of a processing method where high evaluation is given with a decrease in evaluation value is a value obtained by dividing a difference between the summation of the values for all evaluation items and the value for the evaluation item by the summation of the values for all evaluation items. For example, such evaluation items are processing time and accuracy. As a reference, when the evaluation value for the case where the processing method is “substitute mark using” and the evaluation item is “processing time” is calculated from the values shown in Table 3, the calculation formula is set such that {(10+30+120+60)−10}/(10+30+120+60)=0.955, which is as described in Table 4.

TABLE 4

| | | Evaluation value | | |
|---|---|---|---|---|
| | | Success | Processing | |
| Processing | Processing method | rate | time | Accuracy |
| TV pre- | Substitute | 0.800 | 0.955 | 0.789 |
| alignment | mark using | | | |
| measurement | Illumination mode | 0.500 | 0.864 | 0.737 |
| | switching | | | |
| | Mark searching | 0.750 | 0.455 | 0.789 |
| | Substitute shot using | 0.000 | 0.727 | 0.684 |

Furthermore, when there is a plurality of evaluation items (evaluation values) as described above, prioritizing which of these evaluation items may change depending on the difference between processes, lots, or devices in the exposure apparatus 100. This relates to the issue of whether productivity is prioritized or accuracy is prioritized in device manufacturing steps using the exposure apparatus 100. Hence, a plurality of evaluation values may be weighted depending on each process, lot, or device so as to calculate an overall evaluation value for utilization. Table 5 is a table illustrating the results of calculating the overall evaluation values for the processing methods for TV pre-alignment measurement by success rate, processing time, and accuracy in history information in Table 4 as evaluation items. The overall evaluation value is the summation of the integrated values of an evaluation value for each evaluation item and a weight set for each evaluation item as shown in Table 4. Here, in the present embodiment, as an exemplary weight set for each evaluation item, the weight on success rate is “3”, the weight on processing time is “2”, and the weight on accuracy is “1”. In other words, in this example, a heavy weight is placed on the success rate for processing, whereas a light weight is placed on accuracy. As a reference, when the evaluation value for the case where the processing method is “substitute mark using” is calculated from the values shown in Table 4, the calculation formula is set such that (0.8×3)+(0.955×2)+(0.789×1)=5.098, which is as described in Table 5. As described in Table 5, the processing method having the highest overall evaluation value is “substitute mark using”. In other words, the processing method to be firstly selected by the processing method selection unit 102 upon the occurrence of abnormalities during TV pre-alignment measurement is “substitute mark using”.

TABLE 5

| | | Evaluation value | | | |
|---|---|---|---|---|---|
| | | Success | Processing | | |
| | Processing | rate | time | Accuracy | |
| Processing | method | (Weight: 3) | (Weight: 2) | (Weight: 1) | Total |
| TV pre- | Substitute | 2.400 | 1.909 | 0.789 | 5.098 |
| alignment | mark using | | | | |
| measure- | Illumination | 1.500 | 1.727 | 0.737 | 3.964 |
| ment | mode | | | | |
| | switching | | | | |
| | Mark | 2.250 | 0.909 | 0.789 | 3.948 |
| | searching | | | | |
| | Substitute | 0.000 | 1.455 | 0.684 | 2.139 |
| | shot using | | | | |

As described above, according to the present embodiment, not only a recovery time can be reduced but also highly accurate processing can be performed (selected) upon recovery.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-244320 filed on Nov. 6, 2012, which is hereby incorporated by reference herein in its entirety.

What is claimed is:

1. A recovery method for recovering an exposure apparatus that exposes a pattern image onto a substrate in a case that certain processing has not normally ended, the method comprising:
registering a plurality of processing methods to the processing in advance;
determining whether or not the processing has normally ended each time the processing is performed;
associating and storing a number of times the processing has been performed and a number of times the processing has normally ended with the processing method employed when the processing has been performed, as history information; and
selecting the processing method to be next employed from the plurality of processing methods based on the history information in a case that the processing has not normally ended.

2. The recovery method according to claim 1, wherein the history information has specific evaluation items and the plurality of processing methods are selected in order of decreasing priority with reference to the evaluation items in the selecting the processing method.

3. The recovery method according to claim 1, wherein the number of times the processing has been performed and the number of times the processing has normally ended are stored by being associated with the processing method and a plurality of different processing conditions for the processing method.

4. The recovery method according to claim 2, wherein the evaluation items are a success rate calculated by dividing the number of times the processing has normally ended by the number of times the processing has been performed.

5. The recovery method according to claim 4, wherein the evaluation items include the processing time of the processing method in addition to the success rate.

6. The recovery method according to claim 4, wherein the evaluation items include the accuracy of the processing method in addition to the success rate.

7. The recovery method according to claim 5, wherein the priority is determined by applying weight to the plurality of evaluation items.

8. The recovery method according to claim 6, wherein the priority is determined by applying weight to the plurality of evaluation items.

9. The recovery method according to claim 1, wherein the processing is pre-alignment measurement.

10. The recovery method according to claim 9, wherein the processing method includes at least one method of substitute mark using, illumination mode switching, mark searching, and substitute shot using.

11. The recovery method according to claim 1, wherein the processing is provided in plural and a plurality of processing methods is registered in advance to each of the plurality of processings.

12. An exposure apparatus that exposes a pattern image onto a substrate, the apparatus comprising:
a storage unit configured to store a plurality of processing methods to certain processing;
a determination unit configured to determine whether or not the processing has normally ended each time the processing is performed, associate and store a number of times the processing has been performed and a number of times the processing has normally ended with the processing method employed when the processing has been performed, as history information in the storage unit; and
a selection unit configured to select the processing method to be next employed from the plurality of processing methods based on the history information in a case that the processing has not normally ended.
